(19) United States
(12) Patent Application Publication
(10) Pub. No.: US 2024/0222159 A1
(43) Pub. Date: Jul. 4, 2024

(54) BOWL AND APPARATUS FOR PROCESSING SUBSTRATE

(71) Applicant: SEMES CO., LTD., Chungcheongnam-do (KR)

(72) Inventor: Se Hyeong CHOI, Chungcheongnam-do (KR)

(21) Appl. No.: 18/337,515

(22) Filed: Jun. 20, 2023

(30) Foreign Application Priority Data
Dec. 29, 2022 (KR) 10-2022-0188714

(51) Int. Cl. H01L 21/67; H01L 21/687

(52) U.S. Cl. CPC H01L 21/67103; H01L 21/6708; H01L 21/68714

(57) ABSTRACT

A bowl for processing a substrate includes an opening disposed in an upper portion and allowing a substrate to be discharged and input therethrough; a cup configured to form a processing space for processing the substrate; and an edge heating portion provided in the cup and configured to heat an edge of the substrate.

### CROSS-REFERENCE TO RELATED APPLICATIONS

The application claims benefit of priority to Korean Patent Application No. 10-2022-0188714 filed on Dec. 29, 2022 in the Korean Intellectual Property Office, the disclosure of which is incorporated herein by reference in its entirety.

### BACKGROUND

### 1. Field

Example embodiments of the present disclosure relate to a bowl and an apparatus for processing a substrate.

### 2. Description of Related Art

Generally, in a process of manufacturing a semiconductor device, a plurality of membranes such as a polycrystalline film, an oxide film, a nitride film and a metal film are formed in a wafer used as a semiconductor substrate. A photoresist film may be coated on the membrane, and a pattern drawn on a photomask by an exposure process may be transferred to the photoresist film. Thereafter, a desired pattern may be formed on the wafer by an etching process.

An etching apparatus used in an etching process may include a dry etching apparatus and a wet etching apparatus. Among the etching apparatuses, the wet etching apparatus may process a substrate using a plurality of fluids, such as etching, cleaning, and rinse. The apparatus for processing a substrate may perform a process of etching unnecessary portions of a thin film formed on the substrate and a process of cleaning foreign substances remaining in a processing surface of the substrate. The apparatus for processing a substrate may supply high temperature liquid to a substrate in a rotating state to ensure an etch rate, and a temperature difference may occur due to contact with an external airflow from a central portion of the substrate, and accordingly, it may be difficult to maintain uniformity of the etch rate.

### SUMMARY

An example embodiment of the present disclosure is to provide a bowl and an apparatus for processing a substrate which may improve efficiency of processing a substrate.

According to an example embodiment of the present disclosure, a bowl for processing a substrate includes an opening disposed in an upper portion and allowing a substrate to be discharged and input therethrough; a cup configured to form a processing space for processing the substrate; and an edge heating portion provided in the cup and configured to heat an edge of the substrate.

The bowl for processing a substrate may include the at least one cup disposed to surround a support portion supporting the substrate, and the edge heating portion is coupled to an upper internal wall surface of the cup adjacent to the opening.

The edge heating portion may be disposed in a ring shape surrounding an external side of the opening on an upper internal wall surface of the cup.

The edge heating portion may include an edge LED module as a heat source.

The edge heating portion may include an edge light transmissive layer covering the light emitting surface of the edge LED module.

The cup may include a side wall extending upwardly from a bottom surface of the bowl for processing a substrate and an inclined wall inclined upwardly toward the opening from an upper portion of the side wall, and the edge heating portion may be obliquely coupled to an internal wall surface of the inclined wall forming the opening.

A coupling groove to which the edge heating portion may be inserted and coupled is disposed in the cup, and the edge heating portion may form a flat connection surface with an upper end of the coupling groove.

The edge heating portion may include a plurality of edge LED modules surrounding the external side of the opening on an upper internal wall surface of the cup and spaced apart from each other with a predetermined distance therebetween in a circumferential direction of the cup.

The cup may include a side wall extending upwardly from a bottom surface of the bowl for processing a substrate, an inclined wall inclined upwardly toward the opening from an upper portion of the side wall, a vertical wall extending vertically and upwardly from an opening side of the inclined wall, and a guide wall protruding obliquely from a lower portion of the vertical wall toward the side wall, and the edge heating portion may be inserted into and coupled to the guide wall.

According to another example embodiment of the present disclosure, an apparatus for processing a substrate includes a bowl for processing a substrate including an opening disposed in an upper portion and allowing a substrate to be discharged and input therethrough, a cup configured to form a processing space for processing the substrate, and an edge heating portion configured to heat an edge of the substrate, a support portion disposed in the processing space and configured to support the substrate; a supply portion configured to supply liquid to the substrate; and an upper-surface heating portion configured to heat an upper surface of the substrate.

Among the upper-surface heating portion and the edge heating portion, at least the edge heating portion may include an LED module as a heat source.

The edge heating portion may include an edge LED module disposed upwardly of the support portion on an upper internal wall surface of the cup while processing a substrate, and disposed in a ring shape surrounding an external side of the opening.

The edge heating portion may include a plurality of edge LED modules surrounding an external side of the opening on the upper internal wall surface of the cup and spaced apart from each other with a predetermined distance therebetween in a circumferential direction of the cup.

The upper-surface heating portion may have a first heating region covering from a central portion of the substrate a region adjacent to at least an edge of the substrate in a radial direction toward an external side, when viewed from an upper portion, and the edge heating portion may include a second heating region disposed to surround the first heating region and having a ring shape corresponding to an edge of the substrate.

The supply portion may include a driving arm rotatably disposed about a rotational shaft and a supply nozzle disposed on an end of the driving arm and configured to supply liquid to the substrate, and the upper-surface heating portion may be rotatably disposed together with the driving arm and is configured to heat an inner region of at least an edge of an upper surface of the substrate.

The upper-surface heating portion may include an upper-surface LED module extending from a central portion of the substrate to a region adjacent to at least an edge of the substrate in a radial direction toward an external side, when viewed from an upper portion.

At least one of the upper-surface heating portion and the edge heating portion may include a gas spraying portion configured to supply a high-temperature inert gas to the substrate.

The support portion may include a spin chuck configured to support the substrate and a heating member disposed on the spin chuck and configured to heat the substrate.

According to another example embodiment of the present disclosure, an apparatus for processing a substrate includes a process chamber; a bowl for processing a substrate disposed to move up and down by a lifting unit in the process chamber, including an opening in an upper portion thereof and having a processing space for processing a substrate; a support portion disposed in the processing space and including a spin chuck configured to support the substrate and a driving member configured to drive the spin chuck to rotate; a supply portion including a driving arm disposed to rotate around a rotational shaft in the process chamber and a supply nozzle disposed on an end of the driving arm and configured to supply liquid to the substrate; and an upper-surface heating portion disposed to rotate together with the driving arm and including an upper-surface LED module configured to heat an inner region of an edge of an upper surface of the substrate, wherein the bowl for processing a substrate further includes an edge heating portion inserted into and coupled to an upper internal wall surface adjacent to the opening in a ring shape surrounding the opening and including an edge LED module configured to heat an edge of the substrate.

The bowl for processing a substrate may include a first cup surrounding the support portion and having a first recovery space connected to a first inlet port communicating with the opening; a second cup surrounding the first cup and having a second recovery space connected to a second inlet port communicating with the opening in an upper portion of the first inlet port; and a third cup surrounding the second cup and having a third recovery space connected to a third inlet port communicating with the opening in an upper portion of the second inlet port, the edge LED module includes a first cup LED module coupled to an upper internal wall surface of the first cup adjacent to the first inlet port, a second cup LED module coupled to an upper internal wall surface of the second cup adjacent to the second inlet port, and a third cup LED module coupled to an upper internal wall surface of the third cup adjacent to the third inlet port, and the first cup LED module, the second cup LED module and the third cup LED module may be aligned in a vertical direction, and may be inserted into and coupled to an upper internal wall surface of the first cup, an upper internal wall surface of the second cup and an upper internal wall surface of the third cup, respectively.

### BRIEF DESCRIPTION OF DRAWINGS

The above and other aspects, features, and advantages of the present disclosure will be more clearly understood from the following detailed description, taken in conjunction with the accompanying drawings, in which:

FIG. 1 is a diagram illustrating an apparatus for processing a substrate according to example embodiment 1 of the present disclosure;

FIG. 2 is a diagram illustrating an upper-surface heating portion and an edge heating portion with respect to a substrate in an apparatus for processing a substrate according to example embodiment 1 of the present disclosure;

FIG. 3 is a diagram illustrating an upper-surface heating portion and an edge heating portion with respect to a substrate in an apparatus for processing a substrate according to example embodiment 2 of the present disclosure;

FIG. 4 is a diagram illustrating an apparatus for processing a substrate according to example embodiment 3 of the present disclosure;

FIG. 5 is a diagram illustrating an apparatus for processing a substrate according to example embodiment 4 of the present disclosure;

FIG. 6 is a diagram illustrating an apparatus for processing a substrate according to example embodiment 5 of the present disclosure; and

FIG. 7 is a diagram illustrating a bowl for processing a substrate according to example embodiment 6 of the present disclosure.

### DETAILED DESCRIPTION

Hereinafter, example embodiments of the present disclosure will be described as below with reference to the attached drawings. The present disclosure may be implemented in different forms and are not limited to the example embodiments described herein.

In the drawings, same elements will be indicated by same reference numerals. Also, redundant descriptions and detailed descriptions of known functions and elements that may unnecessarily make the gist of the present disclosure obscure will be omitted.

In the example embodiments, the term “connected” may not only refer to “directly connected” but also include “indirectly connected” by means of an adhesive layer, or the like. Also, the term “electrically connected” may include both of the case in which elements are “physically connected” and the case in which elements are “not physically connected.” The terms, “include,” “comprise,” “is configured to,” or the like of the description are used to indicate the presence of features, numbers, operations, operations, elements, portions or combination thereof, and do not exclude the possibilities of combination or addition of one or more features, numbers, operations, operations, elements, portions or combination thereof.

Unless otherwise defined, all terms used herein, including technical or scientific terms, have the same meanings as those generally understood by those with ordinary knowledge in the field of art to which the present invention belongs. Such terms as those defined in a generally used dictionary are to be interpreted as having meanings equal to the contextual meanings in the relevant field of art, and are not to be interpreted as having ideal or excessively formal meanings unless clearly defined as having such in the present application.

### Example Embodiment 1

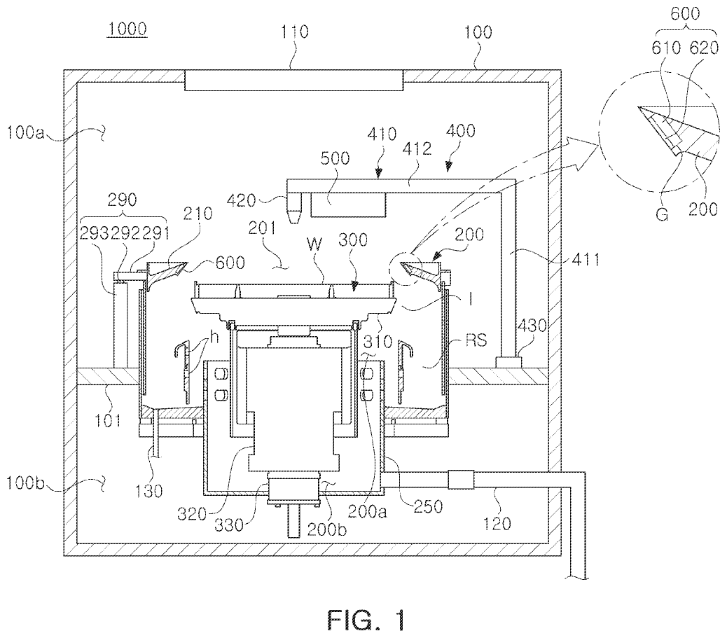

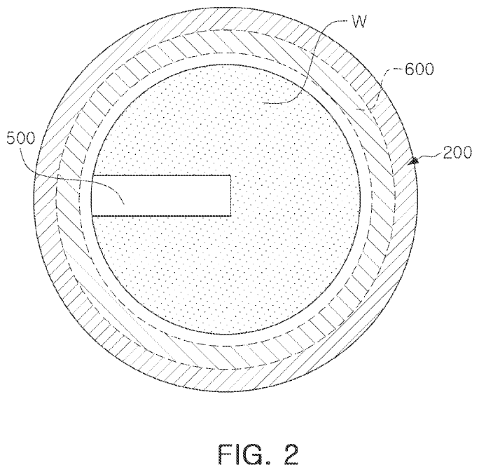

FIG. 1 is a diagram illustrating an apparatus for processing a substrate according to example embodiment. FIG. 2 is a diagram illustrating an upper-surface heating portion and an edge heating portion with respect to a substrate in an apparatus for processing a substrate.

Referring to FIG. 1, the apparatus for processing a substrate in the example embodiment may include a process chamber 100 for performing a process on a substrate W using a liquid. In the process chamber 100, a process may be performed on the substrate W while maintaining the substrate W horizontally. The process chamber 100 may be configured to be used in a process of removing foreign substances and membranes remaining on the surface of the substrate W using various liquids. As a specific example, the process chamber 100 may be a chamber used in a process of removing materials such as photoresist and organic residue on the substrate W. Also, the process chamber 100 may be configured to be used in a process of etching a nitride film formed on the substrate W. In the case, the liquid may include phosphoric acid. However, an example embodiment thereof is not limited thereto and may be applied to various types of apparatus for processing a substrate for supplying a liquid to a substrate.

Specifically, the process chamber 100 provides a sealed internal space, and a fan filter unit 110 may be installed in an upper portion. The fan filter unit 110 may generate a vertical airflow in the process chamber 100. In the fan filter unit 110, a filter and an air supply fan may be modularized into a unit, and may filter clean air and may supply the filtered air into the process chamber 100. The clean air may pass through the fan filter unit 110, may be supplied into the process chamber 100 and may form a vertical airflow. The vertical airflow may provide a uniform air flow to the upper portion of the substrate W, and may remove contaminants (fume) generated in the process of processing the surface of the substrate W by the liquid supplied to the substrate W by discharging the contaminants to the discharge line 130 through the cup 210 of the bowl 200 for processing a substrate, which will be described later, along with air, such that a high level of cleanliness in the bowl 200 for processing a substrate may be maintained.

The process chamber 100 may include a process region 100a and a maintenance region 100b partitioned by a horizontal barrier wall 101. The horizontal barrier wall 101 may include a first driving member 293 of a lifting unit 250 which may drive the bowl 200 for processing a substrate to move up and down with respect to a support portion 300 to be described later, and a second driving member 430 of the nozzle portion 400 installed therein. Also, the maintenance region 100b may be a space in which the discharge line 130 connected to the bowl 200 for processing a substrate and the exhaust member 120 are disposed, and the maintenance region 100b may be isolated from the process region 100a in which the processing of the substrate W is performed.

The apparatus for processing a substrate according to the example embodiment may include a bowl 200 for processing a substrate, a support portion 300 and a supply portion 400 disposed in the process chamber 100. The bowl 200 for processing a substrate may include an opening 201 located in the upper portion and through which the substrate is input and discharged, a cup 210 for forming a processing space for processing the substrate, and an edge heating portion 600 for heating the edge of the substrate to be described later. Specifically, the bowl 200 for processing a substrate may be disposed in the process chamber 100 and may have various shapes such as a cylindrical shape or a polygonal shape having the opening 201 provided in the upper portion, and may have a processing space for processing the substrate W. The opening 201 of the bowl 200 for processing a substrate may be provided as a discharging and inputting passage for the substrate W. Here, a support portion 300 may be disposed in the processing space. In the case, the support portion 300 may support the substrate W and may rotate the substrate W during the process.

Also, the bowl 200 for processing a substrate may provide an upper space 200a in which the spin chuck 310 of the support portion 300 may be disposed, and a lower space 200b connected to the exhaust duct 250 is provided in the lower portion such that forced exhaust may be performed. The exhaust duct 250 may be connected to the exhaust member 120 extending to the outside of the process chamber 100. In the upper space 200a of the bowl 200 for processing a substrate, an annular cup 210 for entering and suctioning liquid and gas scattered on the rotating substrate W may be disposed. That is, the bowl 200 for processing a substrate may include a cup 210 disposed to surround the support portion 300. The cup 210 may have an exhaust port h communicating with an annular space (corresponding to a lower space of the bowl 200 for processing a substrate).

Here, the cup 210 may be disposed to surround the support portion 300 and may have a recovery space RS connected to an inlet port I communicating with the opening 201 of the bowl 200 for processing a substrate. That is, the cup 210 may provide a recovery space RS through which an airflow including liquid and fume scattered from the substrate W may flow in through the inlet port I.

Also, the bowl 200 for processing a substrate may be disposed to move up and down with respect to the support portion 300 by the lifting unit 290. That is, the bowl 200 for processing a substrate may be combined with the lifting unit 290 changing the vertical position of the bowl 200 for processing a substrate. The lifting unit 290 may linearly move the bowl 200 for processing a substrate in a vertical direction. As the bowl 200 for processing a substrate moves up and down, the relative level of the bowl 200 for processing a substrate with respect to the spin chuck 310 of the support portion 300 may change. The lifting unit 290 may have a bracket 291, a moving shaft 292, and a first driving member 293. The bracket 291 may be fixedly installed on the external wall of the bowl 200 for processing a substrate, and the moving shaft 292 moving in the vertical direction by the first driving member 293 may be fixedly coupled to the bracket 291. When the substrate W is loaded into the spin chuck 310 of the support portion 300 or unloaded from the spin chuck 310, the bowl for processing a substrate 200 may move down such that the spin chuck 310 may protrude upwardly from the bowl for processing a substrate 200.

The support portion 300 may be disposed in the processing space of the bowl 200 for processing a substrate and may support the substrate W. The support portion 300 may support the substrate W during the process and may rotate by the third driving member 330 during the process. Also, the support portion 300 may include a spin chuck 310 having a circular upper surface. A support shaft 320 for supporting the spin chuck 310 may be connected to the lower portion of the spin chuck 310, and the support shaft 320 may rotate by a third driving member 330 connected to a lower end thereof. In the case, the third driving member 330 may be provided as a motor, and as the support shaft 320 rotates by the third driving member 330, the spin chuck 310 and the substrate W may rotate.

The supply portion 400 may supply liquid to the substrate W supported by the support portion 300. In the case, the liquid may remove foreign substances or membranes remaining on the surface of the substrate W. In the apparatus for processing a substrate, the liquid supplied from the liquid supply source may be heated such that the liquid may be discharged from the supply nozzle 420 to the substrate W through a liquid supply line (not illustrated). The supply portion 400 may include a driving arm 410 and a supply nozzle 420. Here, the driving arm 410 may rotate and may move up and down by the second driving member 430 connected to the lower portion. The driving arm 410 may extend vertically, and may include a support stand 412 extending to one side from the rotational shaft 411 of which a lower portion is connected to the second driving member 430 and the upper end of the rotational shaft 411, and in which the supply nozzle 420 is disposed. The support stand 412 of the driving arm 410 may be rotatably disposed about the rotational shaft 411 by driving the second driving member 430. Also, the driving arm 410 may be installed in the process chamber 100 and may extend to the upper side of the substrate W. The driving arm 410 may be installed in the process region 100a of the process region 100a on the upper side and the process region (100a) of the maintenance region 100b on the lower side, partitioned by the horizontal barrier wall 101 within the process chamber 100. Also, the supply nozzle 420 may be installed on the end of the driving arm 410 and may be disposed on the upper side of the substrate W.

Generally, by performing a process by supplying a liquid heated at a predetermined temperature to the substrate W supported by the spin chuck 310 in a rotating state, a temperature difference may occur toward the edge as compared to the central portion of the substrate W, and accordingly, efficiency of processing the substrate W may decrease.

To address the issue, the apparatus for processing a substrate according to an example embodiment may include an upper-surface heating portion 500 and an edge heating portion 600.

The upper-surface heating portion 500 may be disposed in the process chamber 100 and may heat the upper surface of the substrate W. Here, the upper-surface heating portion 500 may include various types of heat sources as long as the upper-surface heating portion 500 may heat the liquid supplied to the substrate W by dissipating heat toward the upper surface of the substrate W. Here, in the case of the upper-surface heating portion 500, the heating region for the substrate W in which the heat generated by the upper-surface heating portion 500 may be disposed in a position in which the liquid discharged from the supply nozzle 420 overlaps the region in contact with the substrate W. For ease of description, a heating region for the substrate W of the upper-surface heating portion 500 may be referred to as a first heating region.

The upper-surface heating portion 500 may be disposed to move by a moving means. Specifically, the moving means may be implemented as a driving arm 410 and a second driving member 430 included in the supply portion 400. That is, the upper-surface heating portion 500 may be coupled to the driving arm 410 together with the supply nozzle 420. In other words, the upper-surface heating portion 500 and the supply nozzle 420 may be disposed on the support stand 412 of the driving arm 410 and may rotate and may move up and down together around the rotational shaft 411 by the second driving member 430 connected to the lower portion of the rotational shaft 411. For example, the upper-surface heating portion 500 and the supply nozzle 420 may be disposed side by side in the length direction of the support stand 412. The upper-surface heating portion 500 may provide heat to the vertical lower region for the upper surface of the substrate W, and the supply nozzle 420 may be coupled to the support stand 412 to discharge liquid toward the substrate W. Also, although not illustrated, optionally, the upper-surface heating portion may be disposed to move in the length direction of the support stand in the driving arm. Accordingly, the position of the first heating region with respect to the substrate W may be changed by moving the upper-surface heating portion if desired.

The upper-surface heating portion 500 may heat a region in the edge of the substrate W. The upper-surface heating portion 500 may extend from the central portion of the substrate W to a region adjacent to the edge of the substrate W in a radial direction toward the external side when viewed from the upper portion. For example, as illustrated in FIG. 2, the first heating region of the upper-surface heating portion 500 may have a linear form covering from the central portion of the substrate W to the region adjacent to the edge of the substrate W in the radial direction toward the external side when viewed from the upper portion. However, in the example embodiment, the form of the upper-surface heating portion 500 is not limited to any particular example, and may be implemented in various shapes in which the inner region of the upper surface of the substrate may be efficiently heated. By the configuration of the upper-surface heating portion 500, liquid may be discharged from the supply nozzle 420 to the substrate W supported in a rotating state by the spin chuck 310 of the support portion 300 to perform the process, the upper-surface heating portion 500 may uniformly heat the annular region surrounded by the external side in a radial direction with respect to the central portion of the substrate W in the edge inner region of the substrate W. However, an example embodiment thereof is not limited thereto, and the first heating region of the upper-surface heating portion 500 may extend from the central portion of the substrate W to the edge of the substrate W in the radial direction toward the external side, if desired.

The upper-surface heating portion 500 may include an upper-surface LED module 510 as a heat source. The upper-surface LED module 510 may irradiate light toward the inner region of the edge of the substrate W and may heat the inner region of the edge of the substrate W and the liquid present in the region. The upper-surface LED module 510 may extend from a central portion of the substrate W to at least an inner side or an edge of the substrate W when viewed from above. Here, the upper-surface LED module 510 may irradiate rays of various wavelengths if desired, and may be, for example, an LED irradiating ultraviolet wavelength. However, the upper-surface LED module 510 in the example embodiment is not limited thereto, and may be an LED irradiating rays of various wavelengths, such as infrared wavelengths, near-ultraviolet wavelengths, and near-infrared wavelengths, if desired, and may also irradiate rays of multiple wavelengths. The upper-surface heating portion 500 may heat the liquid present in the inner region of the edge of the substrate W and the inner region of the edge of the substrate W through the upper-surface LED module 510, and may irradiate light, may react with the irradiated light, and may photodecompose or photocure light depending on the type of liquid film on the upper surface of the substrate W, such that uniformity of etching of the liquid film may be maintained, and processing efficiency such as etch rate may improve. The upper-surface heating portion 500 may include a first light transmissive layer (not illustrated) covering the light emitting surface of the upper-surface LED module 510 to protect the upper-surface LED module 510. The first light transmissive layer may be formed of quartz. The upper-surface heating portion 500 may be configured to control the heating temperature. Specifically, the upper-surface heating portion 500 may further include a temperature sensor and may adjust a heating temperature by controlling the output according to the temperature sensed by the temperature sensor. The upper-surface heating portion 500 may be configured to control a heating temperature according to a position in the first heating region. For example, the upper-surface heating portion 500 may control the heating temperature to increase from the central portion of the substrate W toward the external side in the radial direction. However, an example embodiment thereof is not limited thereto, and the heating method of the upper-surface heating portion 500 may be appropriately implemented if desired.

The edge heating portion 600 included in the bowl 200 for processing a substrate may be disposed on the cup 210 and may heat an edge of the substrate W. The edge heating portion 600 may be coupled to an upper internal wall surface of the cup 210 adjacent to the opening 201, and may be disposed in a ring shape surrounding the external side of the opening 201 on the upper internal wall surface of the cup 210. The edge heating portion 600 may be disposed above the support portion 300 in a processing state and may heat the edge of the substrate W supported by the support portion 300 above the substrate W. Specifically, the cup 210 may have a side wall 211 extending upwardly from the bottom surface of the bowl 200 for processing a substrate and an inclined wall 212 disposed upwardly inclined toward the opening 201 in the upper portion of the side wall 211. In the case, the edge heating portion 600 may be disposed on the internal wall surface of the inclined wall 212 adjacent to the opening. The edge heating portion 600 may be disposed in a ring shape surrounding the external side of the opening 201 on the internal wall surface of the inclined wall 212 of the cup 210. Specifically, the edge heating portion 600 may be obliquely coupled to an internal wall surface of the inclined wall 212 forming the opening 201. The liquid on the upper surface of the edge of the substrate W may be heated by uniformly heating the edge of the substrate W through the ring-shaped edge heating portion 600. The edge heating portion 600 may be disposed on the bowl 200 for processing a substrate in various manners. For example, the edge heating portion 600 may be inserted into and coupled to an upper end internal wall surface of the cup 210 of the bowl 200 for processing a substrate. In the case, a coupling groove G may be disposed in the cup 210 of the bowl 200 for processing a substrate. Accordingly, the edge heating portion 600 may be inserted into and coupled to the coupling groove G of the cup 210. In the case, the edge heating portion 600 may form a flat connection surface with the upper end of the coupling groove G. Accordingly, air flow resistance due to the structure of the cup 210 of the bowl 200 for processing a substrate may be reduced, thereby preventing liquid and gas from scattering.

The edge heating portion 600 may include an edge LED module 610 as a heat source. The edge LED module 610 may irradiate light toward the edge of the substrate W and may heat the edge of the substrate W and the liquid present on the edge of the substrate W. Here, the edge LED module 610 may irradiate rays of various wavelengths if desired, and may be, for example, an LED irradiating ultraviolet wavelength. However, the edge LED module 610 in the example embodiment is not limited thereto and may be an LED irradiating rays of various wavelengths, such as infrared wavelengths, near-ultraviolet wavelengths, and near-infrared wavelengths, if desired, and may also irradiate rays of multiple wavelengths. The edge heating portion 600 may heat the edge of the substrate W and the liquid present on the edge of the substrate W through the edge LED module 610, and may also irradiate light and may react with irradiated light and may photodecompose or photocure light depending on the type of liquid film on the surface, such that uniformity of etching the liquid film may be maintained, and processing efficiency such as etch rate may improve. The edge heating portion 600 may have a second heating region for heating an edge of the substrate W. Specifically, the edge heating portion 600 may be disposed to surround the upper-surface heating portion 500 and may have a ring shape corresponding to the edge of the substrate W. Accordingly, the second heating region of the edge heating portion 600 may be disposed to surround the first heating region of the upper-surface heating portion 500 and may have a ring shape corresponding to the edge of the substrate W. The edge heating portion 600 may include an edge LED module 610 formed integrally in a ring shape. However, an example embodiment thereof is not limited thereto and may be implemented in various forms.

The edge heating portion 600 may include an edge light transmissive layer 620 covering a light emitting surface of the edge LED module 610 to protect the edge LED module 610. The edge light transmissive layer 620 may be formed of quartz. The edge light transmissive layer 620 may form a flat light transmissive surface with the internal wall surface of the cup 210 in a state in which the edge heating portion 600 is coupled to the coupling groove G of the cup 210 of the bowl for processing a substrate 200 such that gas and liquid in the bowl 200 for processing a substrate may flow smoothly. That is, the edge light transmissive layer 620 may be disposed so as not to protrude from the coupling groove G of the cup 210 of the bowl 200 for processing a substrate.

Optionally, the edge heating portion 600 may be coupled to the bowl 200 for processing a substrate so as to adjust a heating range for the substrate W. In the case, as the edge heating portion 600 adjusts the heating range for the substrate W, the second heating region may partially overlap the first heating region of the upper-surface heating portion 500. That is, the first heating region of the upper-surface heating portion 500 and the second heating region of the edge heating portion 600 may partially overlap. The edge heating portion 600 may be configured to control heating temperature. Specifically, the edge heating portion 600 may further include a temperature sensor, and the heating temperature may be adjusted by controlling an output according to the temperature sensed by the temperature sensor.

By the above configuration, by heating the liquid on the substrate W and the substrate W by the upper-surface heating portion 500 and the edge heating portion 600, the temperature difference may be addressed for the entire upper surface of the substrate W, also the overall temperature control for the substrate W may be efficiently implemented, and processing efficiency for the substrate W may be improved. Also, a treatment for removing foreign substances and membranes remaining on the surface of substrate W membrane, such as a resist removal treatment using resist peeling liquid such as a sulfuric acid peroxide mixture (SPM) liquid or diluted sulfate peroxide (DSP) liquid, which is an aqueous chemical solution used at high temperatures such as sulfuric acid or phosphoric acid, may be performed through the apparatus for processing a substrate including the upper-surface heating portion 500 and the edge heating portion 600, a selective etching treatment such as nitride film using high-temperature phosphoric acid may also be performed, and uniformity of the etch rate and etch rate may be secured by efficiently controlling the temperature of the liquid, and accordingly, the processing efficiency may improve and the processing time may be shortened.

In the above example embodiment 1, the bowl 200 for processing a substrate has been described as a structure including one cup, but an example embodiment thereof is not limited thereto and may include a plurality of cups.

Also, in example embodiment 1, the upper-surface heating portion 500 and the edge heating portion 600 may include an upper-surface LED module and an edge LED module as heat sources, but an example embodiment thereof is not limited thereto, and various types of heat sources may be included as long as the heat sources may heat the substrate and the liquid on the substrate. For example, a heat source provided with a thermal circuit such as an electric heating coil or a patterned metal thin film may be included.

Also, in example embodiment 1, as a moving means for movably implementing the upper-surface heating portion, the example in which the upper-surface heating portion may be disposed on a driving arm in which a supply nozzle of the supply portion may be disposed has been described, but an example embodiment thereof is not limited thereto, and as another example, the upper-surface heating portion may be disposed on a moving means including another moving arm disposed in the process chamber separately from the driving arm in which the supply nozzle of the supply portion is disposed, and a driving member driving the moving arm.

### Example Embodiment 2

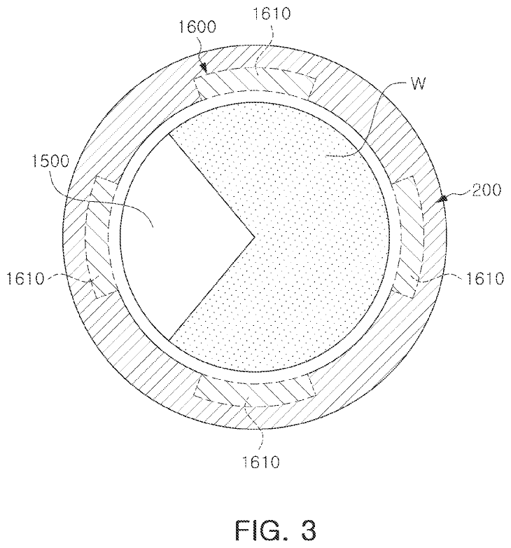

FIG. 3 is a diagram illustrating an upper-surface heating portion and an edge heating portion with respect to a substrate in an apparatus for processing a substrate according to example embodiment 2.

An apparatus for processing a substrate according to example embodiment 2 will be described with reference to FIG. 3.

Referring to the drawing, the configuration other than the configuration in which the forms of the upper-surface heating portion and edge heating portion are different from those of the apparatus for processing a substrate may be the same as that in example embodiment 1, and overlapping descriptions will not be provided.

In the apparatus for processing a substrate according to example embodiment 2, as illustrated in FIG. 3, the upper-surface heating portion 1500 may have a minor arc shape covering the region adjacent to the edge of the substrate W from the central portion of the substrate W toward the external side in the radial direction, viewed from the upper portion. Accordingly, the first heating region of the upper-surface heating portion 1500 may have a minor arc shape covering from the central portion of the substrate W to the region adjacent to the edge of the substrate W in a radial direction toward the external side, when viewed from the upper portion. Here, in the upper-surface heating portion 1500, the upper-surface LED module as a heat source may have a minor arc shape to have a first heating region of a minor arc shape, and a guide member for guiding the heating direction of the upper-surface LED module may be provided to adjust the shape of the first heating region relative to the substrate W. However, in the example embodiment, the shape of the upper-surface heating portion is not limited to any particular example, and various shapes may be implemented as long as the inner region of the upper surface of the substrate may be efficiently heated. By the configuration of the upper-surface heating portion, when the process is performed by supplying liquid to the substrate supported in a rotating state by the support portion, the upper-surface heating portion may uniformly perform a heat treatment to the annular region surrounded by the external side from the inner region at the edge of the substrate in the radial direction with respect to the central portion of the substrate. However, an example embodiment thereof is not limited thereto, and the first heating region of the upper-surface heating portion may extend from the central portion of the substrate to the edge of the substrate in a radial direction toward the external side if desired.

In the apparatus for processing a substrate according to example embodiment 2, as illustrated in FIG. 3, the edge heating portion 1600 of the bowl 200 for processing a substrate may include a plurality of edge LED modules 1610 spaced apart from each other with a predetermined distance therebetween in the circumferential direction from the upper internal wall surface of the cup 210 of the bowl for processing a substrate 200.

### Example Embodiment 3

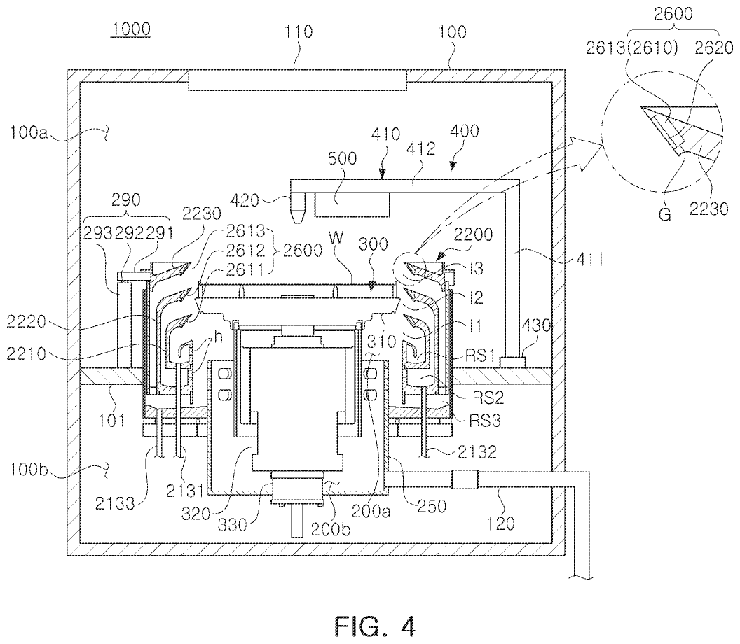

FIG. 4 is a diagram illustrating an apparatus for processing a substrate according to example embodiment 3.

An apparatus for processing a substrate according to example embodiment 3 will be described with reference to FIG. 4.

Referring to the drawing, in the apparatus for processing a substrate according to example embodiment 3, the configuration other than the configuration of the bowl for processing a substrate including a plurality of cups and the edge heating portion disposed in the bowl for processing a substrate may be the same as that in example embodiment 1, and overlapping descriptions will not be provided.

In the apparatus for processing a substrate according to example embodiment 3, the bowl for processing a substrate 2200 may provide an upper space 200a in which the spin chuck 310 of the support portion 300 is disposed and a lower space 200b in which an exhaust duct 250 is connected to the lower portion thereof to perform forced exhaust. The exhaust duct 250 may be connected to the exhaust member 120 extending to the outside of the process chamber 100. In the upper space 200a of the bowl for processing a substrate 2200, first, second and third cups 2210, 2220, and 2230 having an annular shape for entering and suctioning liquid and gas scattered on the rotating substrate W may be disposed in multiple stages. The first, second and third cups 2210, 2220 and 2230 may have exhaust ports h communicating with one common annular space (corresponding to the lower space of the bowl for processing a substrate 2200).

The first cup 2210 may be disposed to surround the support portion 300 and may have a first recovery space RS1 connected to the first inlet port I1. The first inlet port I1 of the first cup 2210 may communicate with the opening of the bowl for processing a substrate 2200. The second cup 2220 may be disposed to surround the first cup 2210 and may be connected to the second inlet port I2 in the upper portion of the first inlet port I1 of the first cup 2210 (a second recovery space RS2. The second inlet port I2 of the second cup 2220 may communicate with the opening of the bowl for processing a substrate 2200. The third cup 2230 may be disposed to surround the second cup 2220 and may have a third recovery space connected to the third inlet port I3 in the upper portion of the second inlet port I2 of the second cup 2220. The third inlet port I3 of the third cup 2230 may communicate with the opening of the bowl for processing a substrate 2200.

That is, the first, second, and third cups 2210, 2220, and 2230 may provide the first, second and third recovery spaces RS1, RS2, and RS3 through which the air flow including the liquid and fume scattered from the substrate W flows in through the first, second, and third inlet ports I1, I2, and I3. The first recovery space RS1 may be partitioned and formed by the first cup 2210, and the second recovery space RS2 may be formed by a spacing between the first cup 2210 and the second cup 2220. The third recovery space RS3 may be formed by a spacing between the second cup 2220 and the third cup 2230.

Also, the bowl for processing a substrate 2200 may be disposed to move up and down with respect to the support portion 300 by the lifting unit 290. That is, the bowl for processing a substrate 2200 may be combined with a lifting unit 290 changing the vertical position of the bowl for processing a substrate 2200. The lifting unit 290 may linearly move the bowl for processing a substrate 2200 in a vertical direction. As the bowl for processing a substrate 2200 moves up and down, the relative level of the bowl for processing a substrate 2200 with respect to the spin chuck 310 may change. The lifting unit 290 may have a bracket 291, a moving shaft 292, and a first driving member 293. The bracket 291 may be fixedly installed on the external wall of the bowl for processing a substrate 2200, and the moving shaft 292 moved in the vertical direction by the first driving member 293 may be fixedly coupled to the bracket 291. When the substrate W is loaded into the spin chuck 310 of the support portion 300 or unloaded from the spin chuck 310, the bowl for processing a substrate 2200 may move down such that the spin chuck 310 may protrude upwardly from the bowl for processing the substrate 2200.

Also, when the process is performed, the level of the bowl for processing a substrate 2200 may be adjusted such that the liquid may flow into a predetermined cup among the first, second and third cups 2210, 2220, and 2230 depending on the type of liquid supplied to the substrate W. Accordingly, the relative vertical position between the bowl for processing a substrate 2200 and the substrate W may be changed. Accordingly, the bowl for processing a substrate 2200 may differentiate the type of liquid and contaminant gas recovered for each recovery space.

The discharge line disposed in the maintenance region 100b of the process chamber 100 and connected to the bow portion 2200 may include the first discharge line 2131 connected to the lower portion of the first cup 2210, a second discharge line 2132 connected to the lower portion of the second cup 2220 and a third discharge line 2133 connected to the lower portion of the third cup 2230. Accordingly, clean air may pass through the fan filter unit 110 of the process chamber 100, may be supplied into the process chamber 100 and may form a vertical airflow. The vertical airflow may provide a uniform air flow to the upper portion of the substrate W, and may remove contaminants (fume) generated in the process of treating the substrate W surface by the liquid supplied to the substrate W by discharging the contaminants to the first, second and third discharge lines 2131, 2132 and 2133 through the first, second and third cups 2210 of the bowl for processing a substrate 2200 along with air, such that a high level of cleanliness in the bowl 200 for processing a substrate may be maintained.

Each of the upper internal wall surface of the first cup 2210 of the bowl for processing a substrate 2200, the upper internal wall surface of the second cup 2220, and the upper internal wall surface of the third cup 2230 may be combined with an edge heating portion 2600. The edge heating portion 2600 may include an edge LED module 2610 coupled to each cup. Specifically, the edge LED module 2610 may include a first cup LED module 2611, a second cup LED module 2612 and a third cup LED module 2613. The first cup LED module 2611 may be coupled to an upper internal wall surface of the first cup 2210 adjacent to the first inlet port I1 of the first cup 2210. A coupling groove G aligned in the vertical direction and to which the first cup LED module 2611 is inserted and coupled may be disposed in the upper internal wall surface of the first cup 2210. The second cup LED module 2612 may be coupled to an upper internal wall surface of the second cup 2220 adjacent to the second inlet port I2 of the second cup 2220. A coupling groove G aligned in the vertical direction and to which the second cup LED module 2612 is inserted and coupled may be disposed in the upper internal wall surface of the second cup 2220. The third cup LED module 2613 may be coupled to an upper internal wall surface of the third cup 2230 adjacent to the third inlet port I3 of the third cup 2230. A coupling groove G aligned in the vertical direction and to which the third cup LED module 2613 is inserted and coupled may be disposed in the upper internal wall surface of the third cup 2230. Also, the edge heating portion 2600 may include an edge light transmissive layer 2620 covering the light emitting surfaces of the first, second, and third cup LED modules 2611, 2612, and 2613, and the edge light transmissive layer 2620 may be formed of quartz.

Accordingly, during the process, the level of the bowl for processing a substrate 2200 may be adjusted by the lifting unit 290 depending on the type of liquid supplied to the substrate W, such that the liquid may flow into a predetermined cup among the first, second, and third cups 2210, 2220, and 2230, and by heating the substrate W and the liquid on the substrate W by the upper-surface heating portion 500 and the first, second and third cup LED modules 2611, 2612, and 2613 of the edge heating portion 2600 disposed in the first, second and third cups 2210, 2220, and 2230, respectively, such that the temperature difference with respect to the entire upper surface of the substrate W may be addressed, also the overall temperature control over the substrate W may be implemented efficiently, and the efficiency of processing the substrate W may improve. Also, a treatment for removing foreign substances and membranes remaining on the surface of substrate W membrane, such as a resist removal treatment using resist peeling liquid such as a sulfuric acid peroxide mixture (SPM) liquid or diluted sulfate peroxide (DSP) liquid, which is an aqueous chemical solution used at high temperatures such as sulfuric acid or phosphoric acid, may be performed through the apparatus for processing a substrate including the upper-surface heating portion 500 and the edge heating portion 2600, a selective etching treatment such as nitride film using high-temperature phosphoric acid may also be performed, and uniformity of the etch rate and etch rate may be secured by efficiently controlling the temperature of the liquid, and accordingly, the processing efficiency may improve and the processing time may be shortened.

In the above example embodiment 3, the bowl for processing a substrate may include three cups, but an example embodiment thereof is not limited thereto and the bowl may include two or more cups if desired.

### Example Embodiment 4

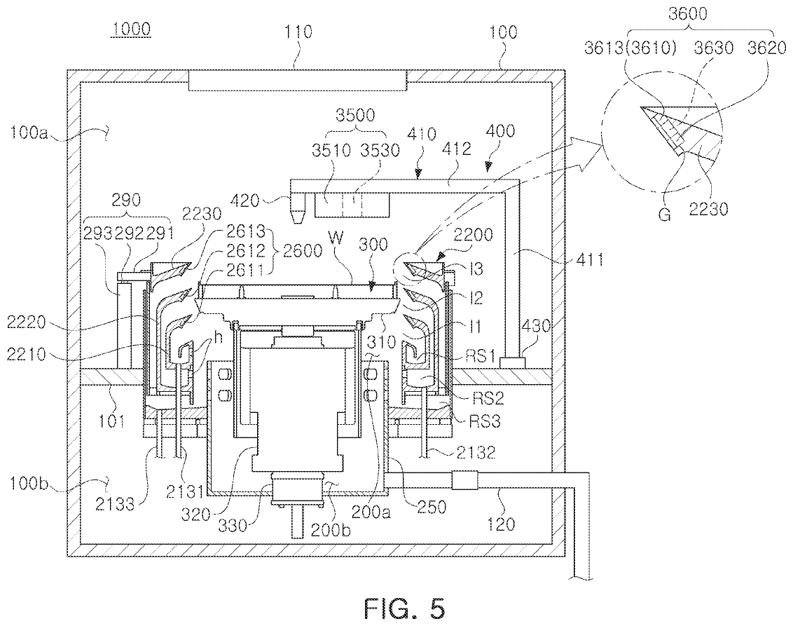

FIG. 5 is a diagram illustrating an apparatus for processing a substrate according to example embodiment 4.

An apparatus for processing a substrate according to example embodiment 4 will be described with reference to FIG. 5.

Referring to the drawing, the configurations other than the configuration of the upper-surface heating portion and the edge heating portion further including a gas spraying portion for supplying a high-temperature inert gas to the substrate in the apparatus for processing a substrate in example embodiment 4 may be the same as in example embodiment 3, and overlapping descriptions will not be provided.

In the apparatus for processing a substrate in the example embodiment, at least one of the upper-surface heating portion 3500 and the edge heating portion 3600 may include a gas spraying portion for supplying high-temperature inert gas to the substrate W. In the example embodiment, each of the upper-surface heating portion 3500 and the edge heating portion 3600 may be configured to include gas spraying.

The upper-surface heating portion 3500 may include an upper-surface LED module 3510 and a first gas spraying portion 3530. The upper-surface LED module 3510 of the upper-surface heating portion 3500 may be configured the same as the upper-surface LED module 510 of the upper-surface heating portion 500 in example embodiment 3 above, and overlapping descriptions will not be provided.

The first gas spraying portion 3530 may be disposed on the upper-surface LED module 3510 and may supply high-temperature inert gas to the substrate W such that the first gas spraying portion 3530 may heat the upper surface of the substrate W and the liquid present on the upper surface of the substrate W or may implement a warming effect.

The edge heating portion 3600 may include an edge LED module 3610 and a second gas spraying portion 3630. Here, the edge heating portion 3600 may further include an edge light transmissive layer 3620 covering the light emitting surface of the edge LED module 3610. The edge LED module 3610 and the edge light transmissive layer 3620 of the edge heating portion 3600 may be configured the same as the edge LED module 2610 of the edge heating portion 2600 in example embodiment 3 above, and overlapping descriptions will not be provided.

The second gas spraying portion 3630 may be disposed on the edge LED module 3610 and may supply high-temperature inert gas to the substrate W such that the second gas spraying portion 3630 may heat the liquid present on the upper surface of the substrate W and the upper surface of the substrate W or may implement a warming effect. Here, the gas supply line of the second gas spraying portion 3630 may be implemented in a form of forming a gas supply flow path in the bowl for processing a substrate or may be implemented as a separate gas supply pipe.

The first gas spraying portion 3530 and the second gas spraying portion 3630 may use nitrogen gas, clean air of a process chamber, or various other inert gases, but are not limited thereto.

By the configuration, by heating the substrate W and the liquid on the substrate W by the upper-surface heating portion 3500 including the upper-surface LED module 3510 and the first gas spraying portion 3530 and the edge heating portion 3600 including the edge LED module 3610 and the second gas spraying portion 3630, the temperature difference may be addressed for the entire upper surface of the substrate W, also overall temperature control may be efficiently implemented and the efficiency of processing the substrate W may be improved. Also, a treatment for removing foreign substances and membranes remaining on the surface of substrate W membrane, such as a resist removal treatment using resist peeling liquid such as a sulfuric acid peroxide mixture (SPM) liquid or diluted sulfate peroxide (DSP) liquid, which is an aqueous chemical solution used at high temperatures such as sulfuric acid or phosphoric acid, may be performed through the apparatus for processing a substrate including the upper-upper-surface heating portion 3500 and edge heating portion 3600, a selective etching treatment such as nitride film using high-temperature phosphoric acid may also be performed, and uniformity of the etch rate and etch rate may be secured by efficiently controlling the temperature of the liquid, and accordingly, the processing efficiency may improve and the processing time may be shortened.

### Example Embodiment 5

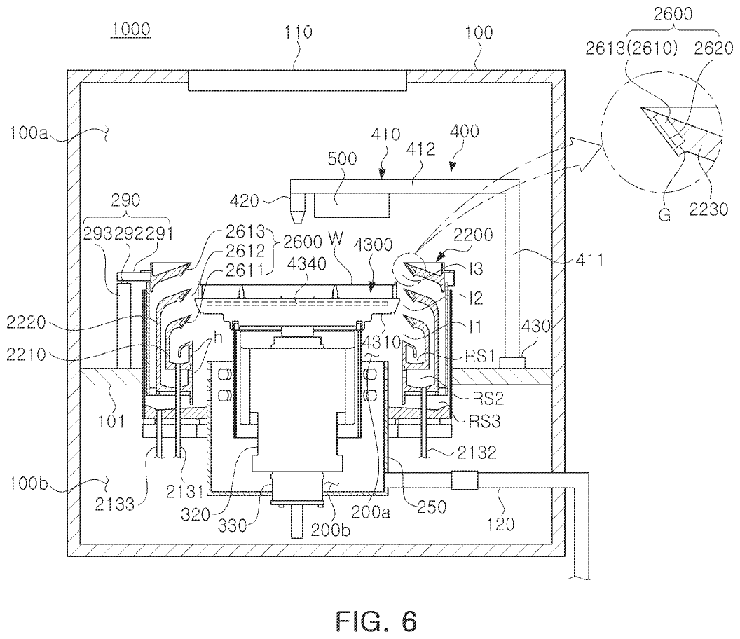

FIG. 6 is a diagram illustrating an apparatus for processing a substrate according to example embodiment 5.

An apparatus for processing a substrate according to example embodiment 5 will be described with reference to FIG. 6.

Referring to the drawings, in the apparatus for processing a substrate according to example embodiment 5, the configuration other than the configuration of the support portion further including a heating member may be the same as in example embodiment 3, and overlapping descriptions will not be provided.

In the apparatus for processing a substrate according to example embodiment 5, the support portion 4300 may further include a heating member 4340 disposed on the spin chuck 4310. Here, the heating member 4340 may be configured in various forms, and may be a heating plate provided with a thermal circuit such as an electric heating coil or a patterned metal thin film. Also, the heating member 4340 may include an LED module for heating the substrate by irradiating light as a heat source, but is not limited thereto.

By the configuration, by heating the liquid on the substrate W and substrate W by the heating member 4340 of the support portion 4300, the upper-surface heating portion 500 and the edge heating portion 600, the temperature difference may be addressed for the entire upper surface of the substrate W, also the overall temperature control for the substrate W may be efficiently implemented, and processing efficiency for the substrate W may be improved. Also, a treatment for removing foreign substances and membranes remaining on the surface of substrate W membrane, such as a resist removal treatment using resist peeling liquid such as a sulfuric acid peroxide mixture (SPM) liquid or diluted sulfate peroxide (DSP) liquid, which is an aqueous chemical solution used at high temperatures such as sulfuric acid or phosphoric acid, may be performed through an apparatus for processing a substrate including the heating member 4340 of the support portion 4300, the upper-surface heating portion 500 and the edge heating portion 600, a selective etching treatment such as nitride film using high-temperature phosphoric acid may also be performed, and uniformity of the etch rate and etch rate may be secured by efficiently controlling the temperature of the liquid, and accordingly, the processing efficiency may improve and the processing time may be shortened.

### Example Embodiment 6

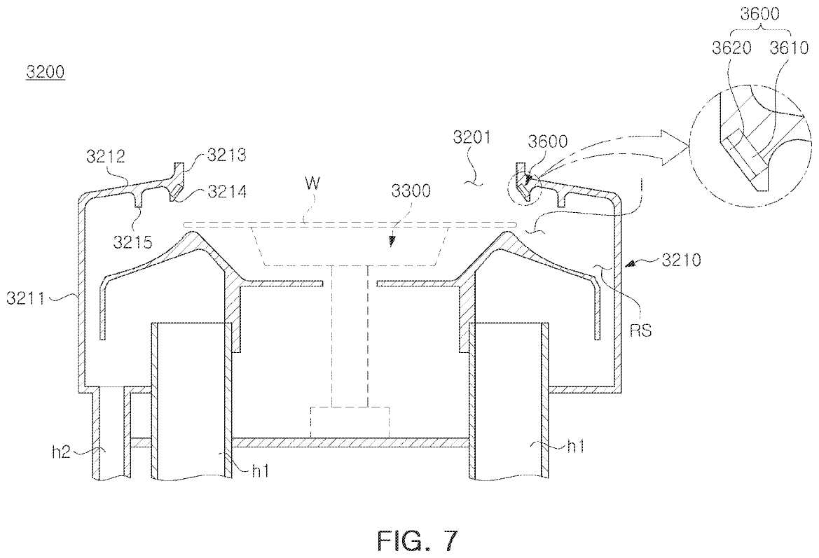

FIG. 7 is a diagram illustrating a bowl for processing a substrate according to example embodiment 6.

A bowl for processing a substrate according to example embodiment 6 will be described with reference to FIG. 7.

Referring to the drawing, a bowl for processing a substrate 3200 according to example embodiment 6 may be configured differently from that of the bowls for processing a substrate 200 and 2200 in example embodiments 1 to 5.

The bowl for processing a substrate 3200 according to example embodiment 6 may be disposed in the upper portion and may include an opening 3201 through which the substrate enters and is discharged, a processing space for processing the substrate, and an edge heating portion for heating the edge of the substrate 3600.

The bowl may have various shapes such as a cylindrical shape or a polygonal shape in which an opening 3201 is provided in the upper portion, and may have a processing space for processing the substrate W. The opening 3201 of the bowl for processing a substrate 3200 may be provided as a path for discharging and inputting the substrate W.

In the processing space of the bowl for processing a substrate 3200, an annular cup 3210 for entering and suctioning liquid and gas scattered on the rotating substrate W may be disposed. That is, the bowl for processing a substrate 3200 may include at least one cup 3210 disposed to surround the support portion 3300 forming the processing space and supporting the substrate W. Although illustrated as one cup 3210 in FIG. 7, a plurality of cups 3210 may be included. The cup 3210 may include an exhaust port h1 for discharging gas and a drain port h2 for discharging liquid on the bottom surface.

Here, the cup 3210 may be disposed to surround the support portion 3300 and may have a recovery space RS connected to the inlet port I communicating with the opening 3201 of the bowl for processing a substrate 3200. That is, the cup 210 may provide a recovery space RS through which an airflow including liquid and fume scattered from the substrate W flows in through the inlet port I.

The cup 3210 may have a side wall 3211 extending upwardly from the bottom surface of the bowl for processing a substrate 3200, an inclined wall 3212 inclined upwardly toward the opening at the upper portion of the side wall 3211, a vertical wall 3213 extending vertically upwardly from the opening 3201 side of the inclined wall 3212, and a guide wall 3214 protruding obliquely from the lower portion of the vertical wall 3213 toward the side wall 3211. Here, the vertical wall 3213 may guide the flow of gas and may form a downward airflow, and may effectively prevent scattering from the substrate W when liquid is supplied to the substrate W in a rotating state. The guide wall 3214 may protrude downwardly from the lower portion of the vertical wall 3213, and specifically, may protrude downwardly from the lower portion of the vertical wall 3213 toward the external side of the opening 3201 of the cup 3210 in the circumferential direction. By the configuration, the gas flowing in along the vertical section of the vertical wall 3213 may flow uniformly into the processing space of the bowl for processing a substrate 3200 along the guide wall 3214, such that uniformity of gas flow into the bowl for processing a substrate 3200 may improve, and also, the gas exhaust efficiency may be improved. Also, the liquid scattered from the substrate W and gas flowing therefrom in the bowl for processing a substrate 3200 may flow downwardly of the bowl for processing a substrate 3200 by the guide of the guide wall 3214, such that back flow of liquid and gas may be prevented, and re-adhesion of liquid to the substrate W may be prevented.

To prevent reverse flow of liquid and gas flowing through the processing space of the bowl for processing a substrate 3200, the cup 3210 may further include a moving guide wall 3215 disposed on an internal wall surface of the inclined wall 3212. The moving guide wall 3215 may be disposed between the guide wall 3214 and the side wall 3211 of the bowl for processing a substrate 3200 and may protrude downwardly from the internal wall surface of the inclined wall 3212 in a vertical direction. A lower end of the moving guide wall 3215 may be disposed on a level higher than a level of an upper surface of a spin chuck of the support portion 3300 in a vertical direction. By the configuration of the moving guide wall 3214, the liquid and gas flowing in from the substrate W may flow downward by the guide of the moving guide wall 3215, such that back flow of liquid and gas in the direction of the substrate W may be prevented, and re-adhesion of liquid to the substrate W may be prevented, and accordingly, process defects may be effectively prevented.

The edge heating portion 3600 may be inserted into and coupled to the guide wall 3214. Specifically, a coupling groove G to which the edge heating portion 3600 is inserted and coupled may be disposed on the guide wall 3214 of the cup 3210.

The edge heating portion 3600 may include an edge LED module 3610 as a heat source. The edge LED module 3610 may irradiate light toward the edge of the substrate W and may heat the edge of the substrate W and the liquid present on the edge of the substrate W. The edge heating portion 3600 may include an edge light transmissive layer 3620 covering a light emitting surface of the edge LED module 3610 to protect the edge LED module 3610. The configuration of the edge heating portion 3600 may be the same as the configuration of the edge heating portion 600 in example embodiment 1 or example embodiment 2.

According to the aforementioned example embodiments, the edge of the substrate and the liquid at the edge of the substrate may be heated through the edge heating portion provided in the cup of the apparatus for processing a substrate during substrate processing, such that efficiency of processing a substrate may be improved.

Also, by heating the liquid on the substrate and the substrate by the upper-surface heating portion and edge heating portion, not only may the temperature difference for the entire upper surface of the substrate be improved, but also the overall temperature control for the substrate may be efficiently implemented, and the efficiency of Processing a substrate may be improved.

While the example embodiments have been illustrated and described above, it will be apparent to those skilled in the art that modifications and variations could be made without departing from the scope of the present disclosure as defined by the appended claims.

What is claimed is:

1. A bowl for processing a substrate, the bowl comprising:
an opening disposed in an upper portion and allowing a substrate to be discharged and input therethrough;
a cup configured to form a processing space for processing the substrate; and
an edge heating portion provided in the cup and configured to heat an edge of the substrate.

2. The bowl for processing a substrate of claim 1, further comprising:
the at least one cup disposed to surround a support portion supporting the substrate,
wherein the edge heating portion is coupled to an upper internal wall surface of the cup adjacent to the opening.

3. The bowl for processing a substrate of claim 2, wherein the edge heating portion is disposed in a ring shape surrounding an external side of the opening on an upper internal wall surface of the cup.

4. The bowl for processing a substrate of claim 3, wherein the edge heating portion includes an edge LED module as a heat source.

5. The bowl for processing a substrate of claim 4, wherein the edge heating portion includes an edge light transmissive layer covering the light emitting surface of the edge LED module.

6. The bowl for processing a substrate of claim 2, wherein the cup includes a side wall extending upwardly from a bottom surface of the bowl for processing a substrate and an inclined wall inclined upwardly toward the opening from an upper portion of the side wall, and the edge heating portion is obliquely coupled to an internal wall surface of the inclined wall forming the opening.

7. The bowl for processing a substrate of claim 1, wherein a coupling groove to which the edge heating portion is inserted and coupled is disposed in the cup, and the edge heating portion forms a flat connection surface with an upper end of the coupling groove.

8. The bowl for processing a substrate of claim 2, wherein the edge heating portion includes a plurality of edge LED modules surrounding the external side of the opening on an upper internal wall surface of the cup and spaced apart from each other with a predetermined distance therebetween in a circumferential direction of the cup.

9. The bowl for processing a substrate of claim 2,
wherein the cup includes a side wall extending upwardly from a bottom surface of the bowl for processing a substrate, an inclined wall inclined upwardly toward the opening from an upper portion of the side wall, a vertical wall extending vertically and upwardly from an opening side of the inclined wall, and a guide wall protruding obliquely from a lower portion of the vertical wall toward the side wall, and
wherein the edge heating portion is inserted into and coupled to the guide wall.

10. An apparatus for processing a substrate, the apparatus comprising:
a bowl for processing a substrate including an opening disposed in an upper portion and allowing a substrate to be discharged and input therethrough, a cup configured to form a processing space for processing the substrate, and an edge heating portion configured to heat an edge of the substrate,
a support portion disposed in the processing space and configured to support the substrate;
a supply portion configured to supply liquid to the substrate; and
an upper-surface heating portion configured to heat an upper surface of the substrate.

11. The apparatus for processing a substrate of claim 10, wherein, among the upper-surface heating portion and the edge heating portion, at least the edge heating portion includes an LED module as a heat source.

12. The apparatus for processing a substrate of claim 10, wherein the edge heating portion includes an edge LED module disposed upwardly of the support portion on an upper internal wall surface of the cup while processing a substrate, and disposed in a ring shape surrounding an external side of the opening.

13. The apparatus for processing a substrate of claim 10, wherein the edge heating portion includes a plurality of edge LED modules surrounding an external side of the opening on the upper internal wall surface of the cup and spaced apart from each other with a predetermined distance therebetween in a circumferential direction of the cup.

14. The apparatus for processing a substrate of claim 10,
wherein the upper-surface heating portion has a first heating region covering from a central portion of the substrate a region adjacent to at least an edge of the substrate in a radial direction toward an external side, when viewed from an upper portion, and
wherein the edge heating portion includes a second heating region disposed to surround the first heating region and having a ring shape corresponding to an edge of the substrate.

15. The apparatus for processing a substrate of claim 10,
wherein the supply portion includes a driving arm rotatably disposed about a rotational shaft and a supply nozzle disposed on an end of the driving arm and configured to supply liquid to the substrate, and
wherein the upper-surface heating portion is rotatably disposed together with the driving arm and is configured to heat an inner region of at least an edge of an upper surface of the substrate.

16. The apparatus for processing a substrate of claim 15, wherein the upper-surface heating portion includes an upper-surface LED module extending from a central portion of the substrate to a region adjacent to at least an edge of the substrate in a radial direction toward an external side, when viewed from an upper portion.

17. The apparatus for processing a substrate of claim 10, wherein at least one of the upper-surface heating portion and the edge heating portion includes a gas spraying portion configured to supply a high-temperature inert gas to the substrate.

18. The apparatus for processing a substrate of claim 10, wherein the support portion includes a spin chuck configured to support the substrate and a heating member disposed on the spin chuck and configured to heat the substrate.

19. An apparatus for processing a substrate, the apparatus comprising:
a process chamber;
a bowl for processing a substrate disposed to move up and down by a lifting unit in the process chamber, including an opening in an upper portion thereof and having a processing space for processing a substrate;
a support portion disposed in the processing space and including a spin chuck configured to support the substrate and a driving member configured to drive the spin chuck to rotate;
a supply portion including a driving arm disposed to rotate around a rotational shaft in the process chamber and a supply nozzle disposed on an end of the driving arm and configured to supply liquid to the substrate; and
an upper-surface heating portion disposed to rotate together with the driving arm and including an upper-surface LED module configured to heat an inner region of an edge of an upper surface of the substrate,
wherein the bowl for processing a substrate further includes an edge heating portion inserted into and coupled to an upper internal wall surface adjacent to the opening in a ring shape surrounding the opening and including an edge LED module configured to heat an edge of the substrate.

20. The apparatus for processing a substrate of claim 19,
wherein the bowl for processing a substrate includes:
a first cup surrounding the support portion and having a first recovery space connected to a first inlet port communicating with the opening;
a second cup surrounding the first cup and having a second recovery space connected to a second inlet port communicating with the opening in an upper portion of the first inlet port; and
a third cup surrounding the second cup and having a third recovery space connected to a third inlet port communicating with the opening in an upper portion of the second inlet port,
wherein the edge LED module includes a first cup LED module coupled to an upper internal wall surface of the first cup adjacent to the first inlet port, a second cup LED module coupled to an upper internal wall surface of the second cup adjacent to the second inlet port, and a third cup LED module coupled to an upper internal wall surface of the third cup adjacent to the third inlet port, and
wherein the first cup LED module, the second cup LED module and the third cup LED module are aligned in a vertical direction, and are inserted into and coupled to an upper internal wall surface of the first cup, an upper internal wall surface of the second cup and an upper internal wall surface of the third cup, respectively.
